(19) United States
(12) Patent Application Publication
(10) Pub. No.: US 2012/0044654 A1
(43) Pub. Date: Feb. 23, 2012

(54) FIXING MECHANISM FOR FIXING A REMOVABLE MODULE AND RELATED ELECTRONIC DEVICE

(76) Inventors: Cheng-Min Hsiu, New Taipei City (TW); Che-Sheng Yang, New Taipei City (TW)

(21) Appl. No.: 13/192,472

(22) Filed: Jul. 28, 2011

(30) Foreign Application Priority Data
Aug. 19, 2010 (TW) 099215942

(51) Int. Cl. H05K 7/00; E05C 5/02

(52) U.S. Cl. 361/747; 292/62

(57) ABSTRACT

A fixing mechanism includes a housing whereon an accommodating space and a fastening slot are formed. The accommodating space is for accommodating a removable module. The fixing mechanism further includes a casing for covering the removable module. The fixing mechanism further includes a latch component installed on the casing in a slidable manner, and a handle connected to the casing in a rotatable manner. An end of the handle pushes the latch component to engage inside the fastening slot for fixing the removable module inside the accommodating space when the handle rotates to a fixing position. The fixing mechanism further includes a resilient component connected to the latch component for driving the latch component to separate from the fastening slot when the handle rotates to a releasing position and the end of the handle separates from the latch component.

### BACKGROUND OF THE INVENTION

1. Field of the Invention

The present invention relates to a fixing mechanism and a related electronic device, and more particularly, to a fixing mechanism for fixing a removable module without utilizing screws and a related electronic device.

2. Description of the Prior Art

A computer has to be disassembled for replacing broken components, installing new components, upgrading the components, and so on. The computer with easy disassembly characteristic suits a user's demand. It is also convenient for users to disassemble a storage device, such as a hard disk, from a computer. Generally speaking, most of the hard disc devices of the notebook computer are of removable mechanism design. However, the design still needs to screw components between the removable storage device and a host resulting in difficulty of assembly and increase of labor hour of assembly.

### SUMMARY OF THE INVENTION

The present invention provides a fixing mechanism for fixing a removable module without utilizing screws and a related electronic device for solving above drawbacks.

According to the claimed invention, a fixing mechanism includes a housing whereon an accommodating space and a fastening slot are formed. The accommodating space is used for accommodating the removable module. The fixing mechanism further includes a casing for covering the removable module and a latch component installed on the casing in a slidable manner. The fixing mechanism further includes a handle connected to the casing in a rotatable manner. An end of the handle pushes the latch component to engage inside the fastening slot for fixing the removable module inside the accommodating space when the handle rotates to a fixing position. The fixing mechanism further includes a resilient component connected to the latch component for driving the latch component to separate from the fastening slot when the handle rotates to a releasing position and the end of the handle separates from the latch component.

According to the claimed invention, the casing comprises a guiding post, and the housing comprises a track and a hole. The track is used for guiding the guiding post to move in an inclined direction so as to be inserted into the hole.

According to the claimed invention, the casing comprises a wedging part for engaging the handle when the handle rotates to the fixing position.

According to the claimed invention, the fixing mechanism further comprises a pin disposed on the casing. The end of the handle sheathes the pin so as to be pivotally connected to the casing.

According to the claimed invention, a protruding part is disposed at the end of the handle for pushing the latch component.

According to the claimed invention, the latch component comprises a positioning post, the resilient component sheathes the positioning post, and an end of the resilient component abuts against the casing and the other end of the resilient component abuts against the latch component.

According to the claimed invention, the resilient component is a spring.

According to the claimed invention, a slot is formed on the latch component, and the casing comprises a hook engaging inside the slot of the latch component in a slidable manner.

According to the claimed invention, an inclined structure is formed on an end of the latch component, and the inclined structure is used for guiding the end of the latch component to be disposed in the fastening slot.

According to the claimed invention, an electronic device includes a removable module and a fixing mechanism for fixing the removable module. The fixing mechanism includes a housing whereon an accommodating space and a fastening slot are formed. The accommodating space is used for accommodating the removable module. The fixing mechanism further includes a casing for covering the removable module and a latch component installed on the casing in a slidable manner. The fixing mechanism further includes a handle connected to the casing in a rotatable manner. An end of the handle pushes the latch component to engage inside the fastening slot for fixing the removable module inside the accommodating space when the handle rotates to a fixing position. The fixing mechanism further includes a resilient component connected to the latch component for driving the latch component to separate from the fastening slot when the handle rotates to a releasing position and the end of the handle separates from the latch component.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are diagrams of an electronic device in different statuses respectively according to a preferred embodiment of the present invention.

FIG. 4 is an exploded diagram of the electronic device according to the preferred embodiment of the present invention.

FIG. 5 is an internal structural diagram of the electronic device in another view according to the preferred embodiment of the present invention.

FIG. 6 is a perspective drawing of a fixing mechanism in another view according to the preferred embodiment of the present invention.

FIG. 7 and FIG. 8 are diagrams of a latch component in different statuses according to the preferred embodiment of the present invention.

FIG. 9 to FIG. 12 are partial sectional views of the electronic device in different statuses and in different views according to the preferred embodiment of the present invention.

### DETAILED DESCRIPTION

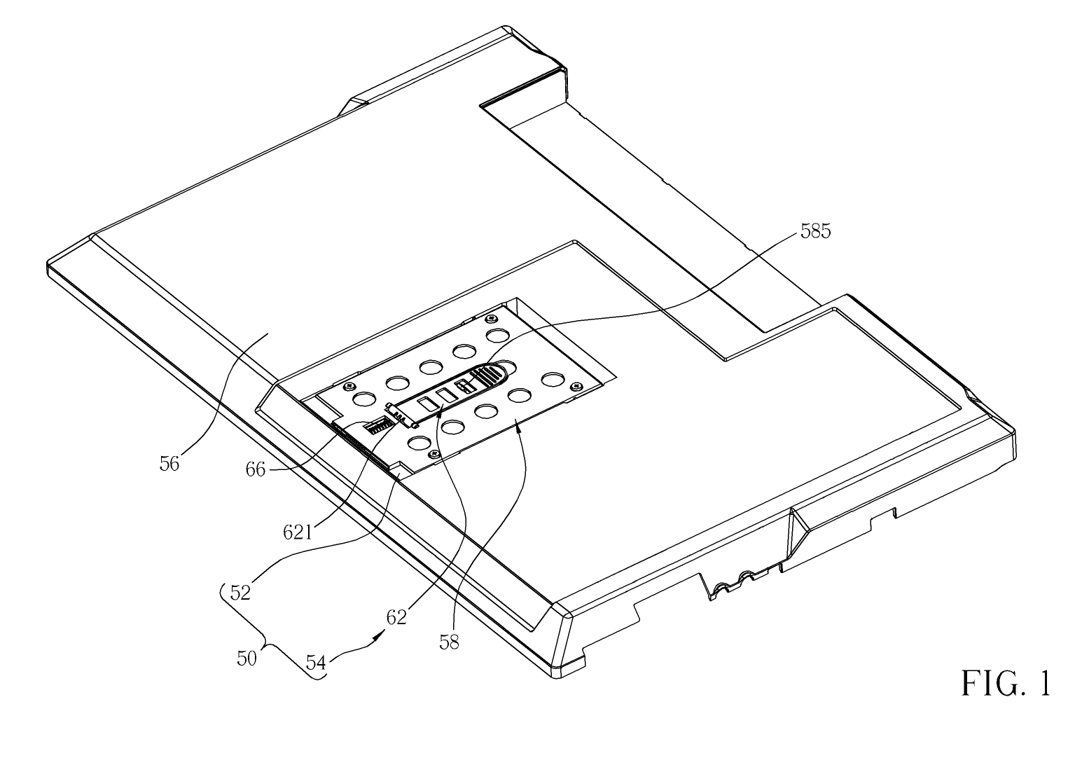

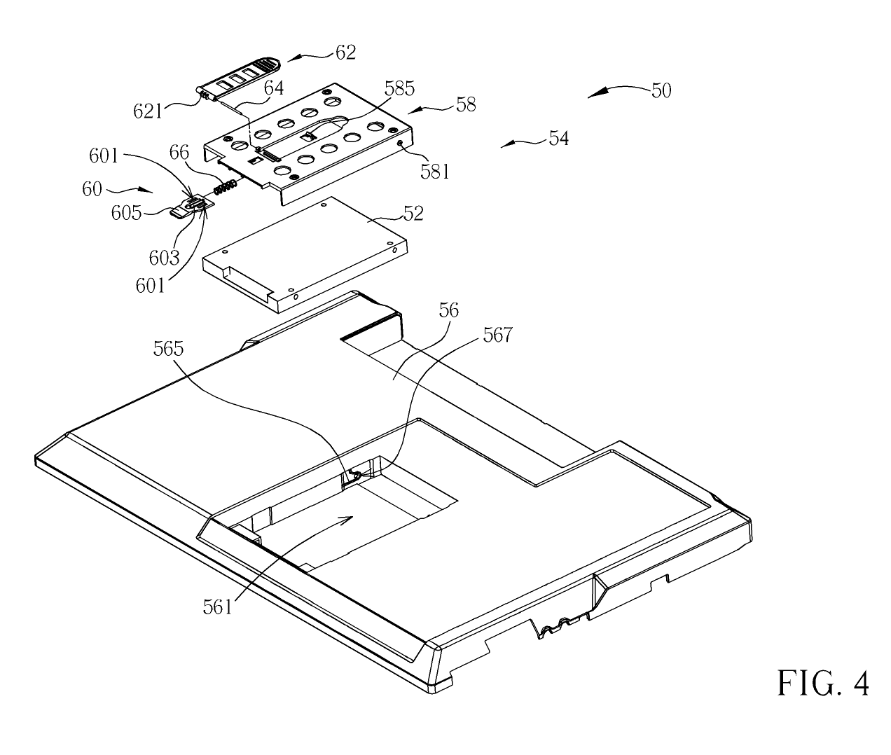

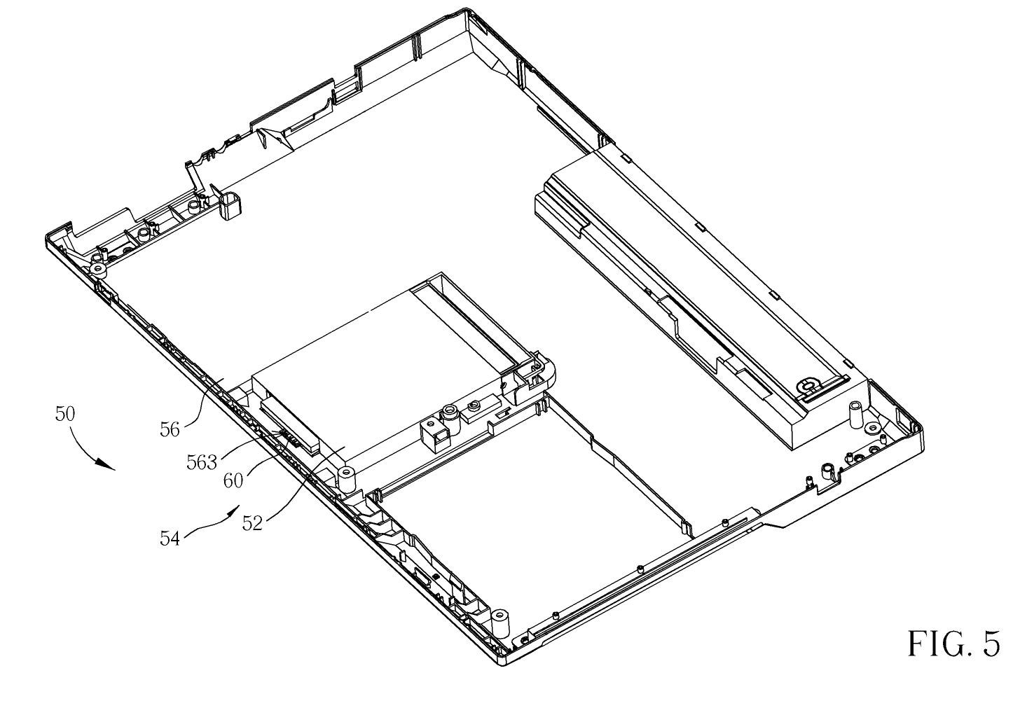

Please refer to FIG. 1 to FIG. 5. FIG. 1 to FIG. 3 are diagrams of an electronic device 50 in different statuses respectively according to a preferred embodiment of the present invention. FIG. 4 is an exploded diagram of the electronic device 50 according to the preferred embodiment of the present invention. FIG. 5 is an internal structural diagram of the electronic device 50 in another view according to the preferred embodiment of the present invention. The electronic device 50 can be a portable computer such as a notebook computer and so on. The electronic device 50 includes a removable module 52 which can be a storage module, such as a hard disk drive or an optical disk drive and so on. The electronic device 50 further includes a fixing mechanism 54 for fixing the removable module 52. The fixing mechanism 54 includes a housing 56 whereon an accommodating space 561 and a fastening slot 563 are formed. The housing 56 can be a bottom cover of a host of the electronic device 50, and the accommodating space 561 is used for accommodating the removable module 52. The housing 56 further includes at least one track 565 and at least one hole 567. As shown in the figures, the track 565 and the hole 567 are disposed on both sides of the accommodating space 561, and the track 565 can be an inclined track for easy disassemble of the removable module 52. The fixing mechanism 54 further includes a casing 58 for covering the removable module 52. For example, the casing 58 can be locked on an outer side of the removable module 52, and the casing 58 includes at least one guiding post 581. When the removable module 52 is going to be installed in the accommodating space 561 of the housing 56, the removable module 52 is obliquely disposed so as to make the guiding post 581 of the casing 58 be obliquely disposed in the track 565 of the housing 56. At this time, the track 565 can guide the guiding post 581 to move obliquely to its terminal so as to make the guiding post 581 be inserted into the hole 567 of the housing 56. In such a manner, the removable module 52 can be stably fastened in the accommodating space 561 of the housing 56.

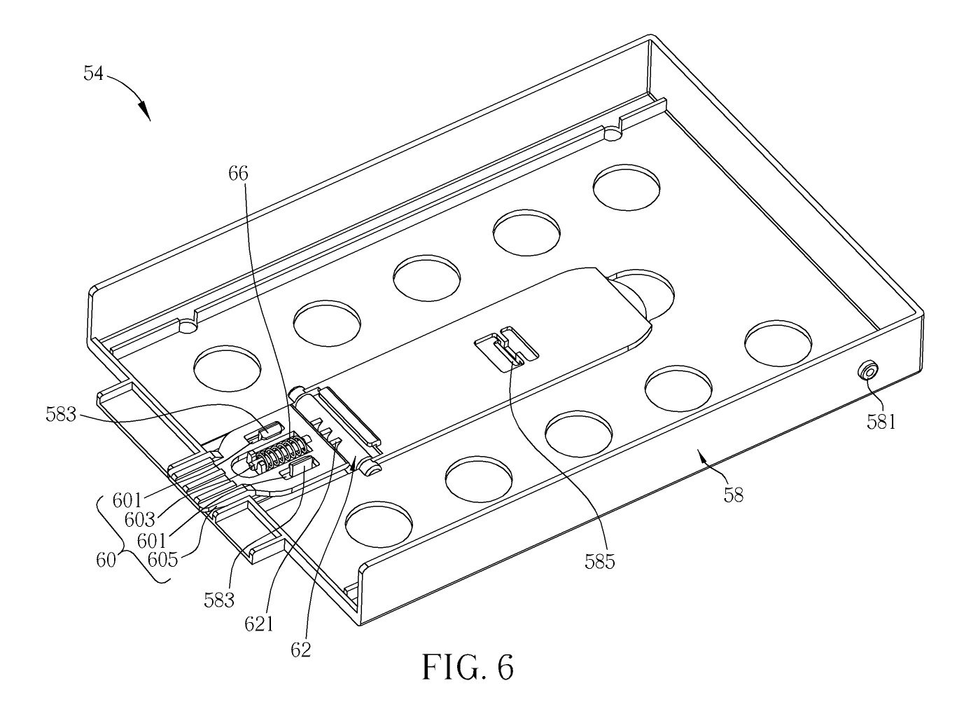

The fixing mechanism 54 further includes a latch component 60 installed on the casing 58 in a slidable manner. Please refer to FIG. 4 to FIG. 6. FIG. 6 is a perspective drawing of the fixing mechanism 54 in another view according to the preferred embodiment of the present invention. At least one slot 601 is formed on the latch component 60, and the casing 58 includes at least one hook 583 engaging inside the slot 601 of the latch component 60 in a slidable manner. A combination of the hook 583 and the slot 601 constrains the latch component 60 to slide in a single direction relative to the casing 58. As for a mechanism for constraining the latch component 60 to slide relative to the casing 58, it is not limited to the aforementioned structure, e.g. a positioning wall can be disposed on a side of the latch component 60, and it depends on design demand. The fixing mechanism 54 further includes a handle 62 connected to the casing 58 in a rotatable manner. For example, the fixing mechanism 54 can further include a pin 64 installed on the casing 58. An end of the handle 62 sheathes the pin 64 so as to be pivotally connected to the casing 58. A protruding part 621 is disposed at the end of the handle 62 to push the latch component 60, so as to make the latch component 60 engage inside the fastening slot 563 of the housing 56. The fixing mechanism 54 further includes a resilient component 66 connected to the latch component 60 for driving the latch component 60 to separate from the fastening slot 563. The resilient component 66 can be a spring. For example, the latch component 60 can include a positioning post 603, and the resilient component 66 sheathes the positioning post 603. An end of the resilient component 66 abuts against the casing 58 and the other end of the resilient component 66 abuts against the latch component 60. When the latch component 60 is pushed by the protruding part 621 of the handle 62 to move toward the fastening slot 563 of the housing 56, the latch component 60 pushes the other end of the resilient component 66 resulting in compression of the resilient component 66. When the protruding part 621 of the handle 62 separates from the latch component 60, the resilient component 66 recovers from the compressed state to an initial state. That is, the resilient component 66 provides the latch component 60 with an elastic restoring force so as to drive the latch component 60 to separate from the fastening slot 563.

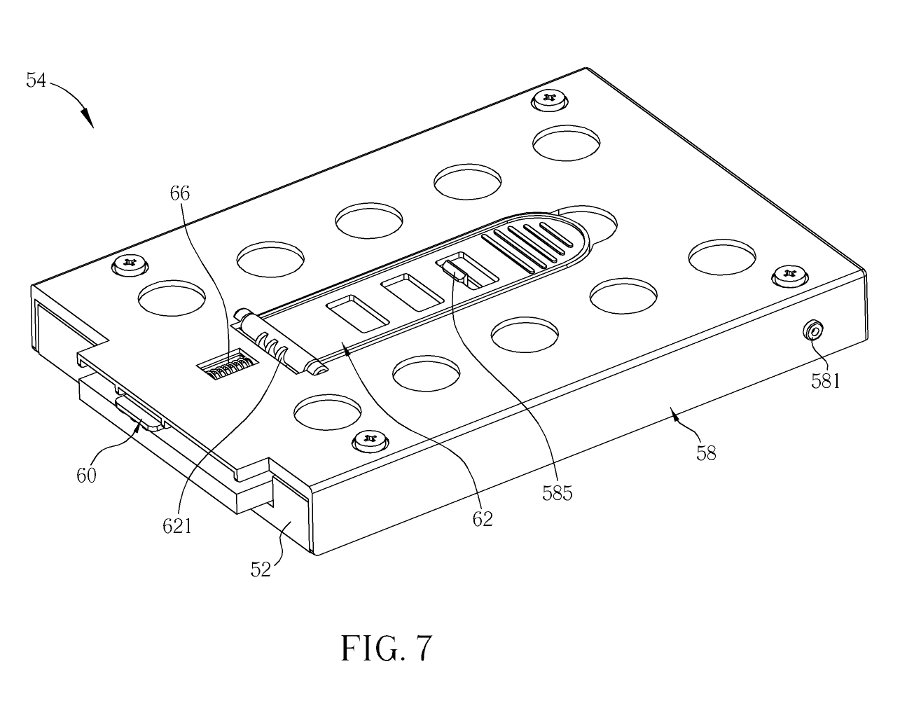

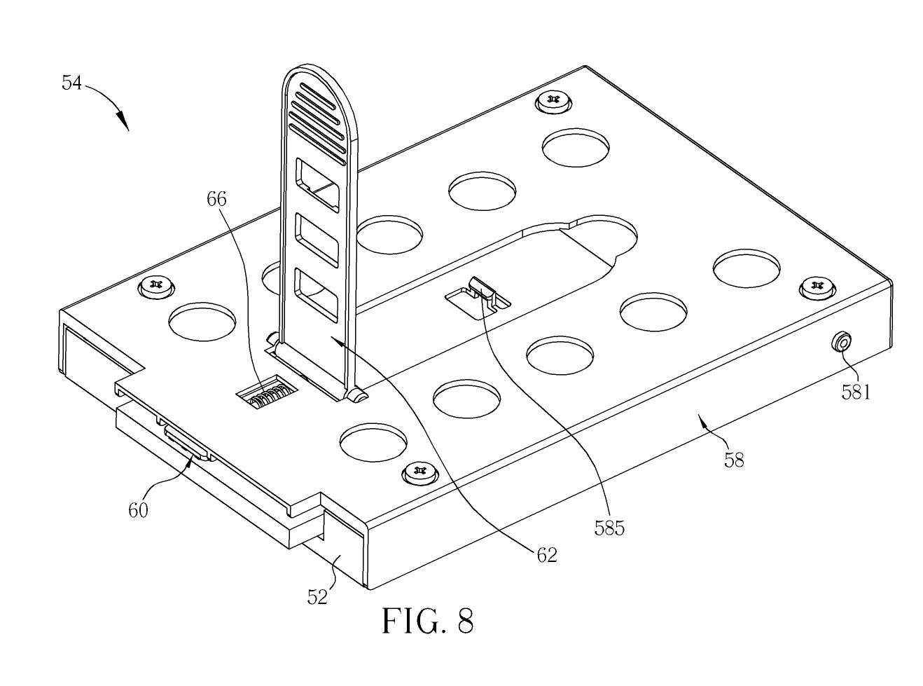

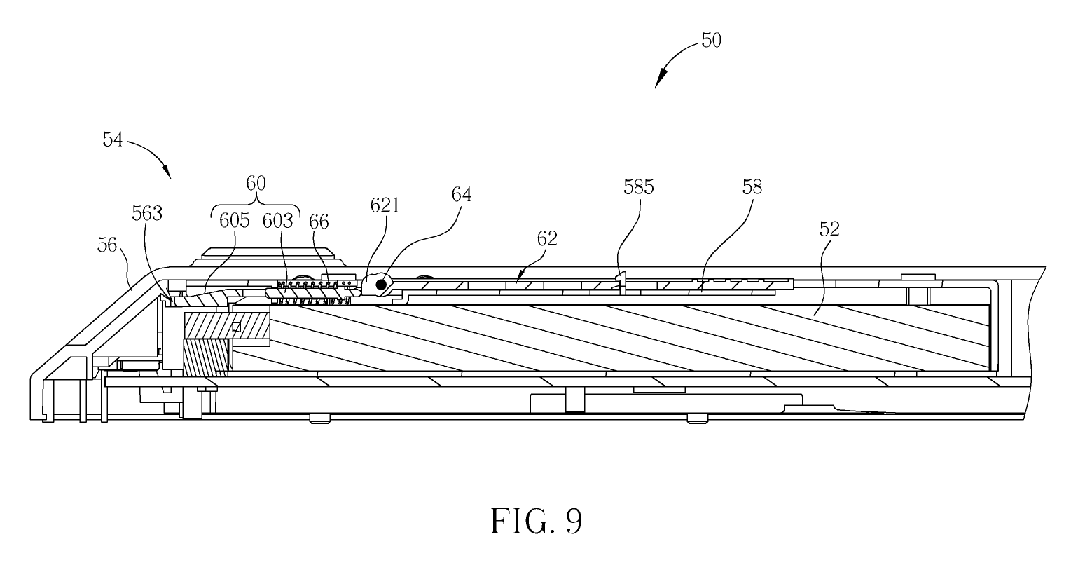

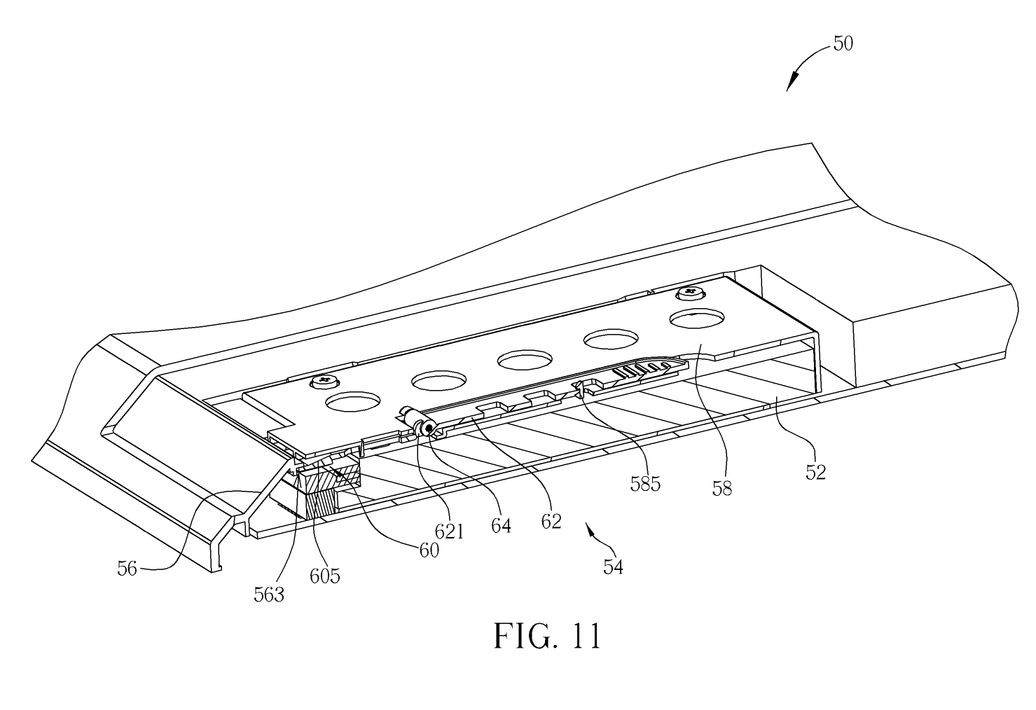

Please refer to FIG. 1 to FIG. 3 and FIG. 7 to FIG. 12. FIG. 7 and FIG. 8 are diagrams of the latch component 60 in different statuses according to the preferred embodiment of the present invention. FIG. 9 to FIG. 12 are partial sectional views of the electronic device 50 in different statuses and in different views according to the preferred embodiment of the present invention. As shown in FIG. 1, FIG. 6, FIG. 7, FIG. 9 and FIG. 11, the handle 62 rotates to a fixing position when the removable module 52 is installed in the accommodating space 561 of the housing 56. At this time, the protruding part 621 of the handle 62 abuts against the latch component 60 and pushes the latch component 60 to be engaged inside the fastening slot 563, and the guiding post 581 is inserted into the hole 567 of the housing 56. Accordingly, the removable module 52 can be stably fastened in the accommodating space 561 of the housing 56, and at this time, the other end of the resilient component 66 is pushed by the latch component 60 so that the resilient component 66 is compressed. In addition, the casing 58 further includes a wedging part 585, and the wedging part 585 can be a hook. The wedging part 585 engages the handle 62 when the handle 62 rotates to the fixing position so as to avoid the handle 62 from loosing. Furthermore, an inclined structure 605 can be selectively formed on an end of the latch component 60 for guiding the end of the latch component 60 to enter in the fastening slot 563 when the latch component 60 is pushed by the protruding part 621 of the handle 62.

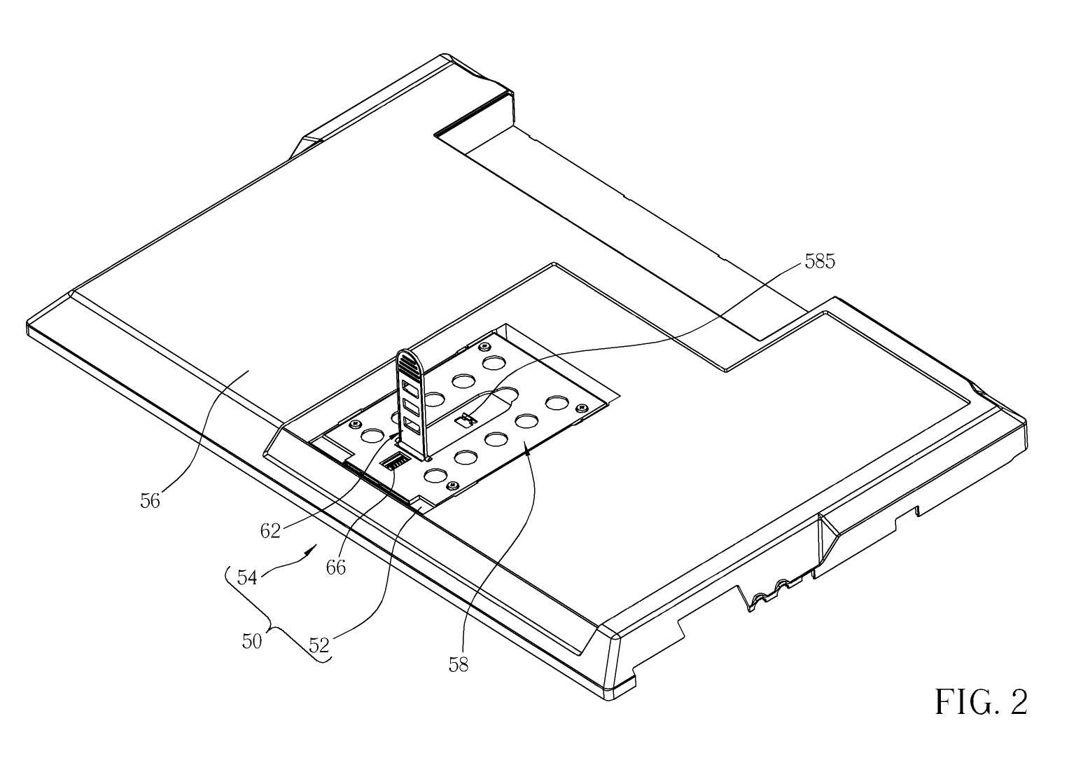

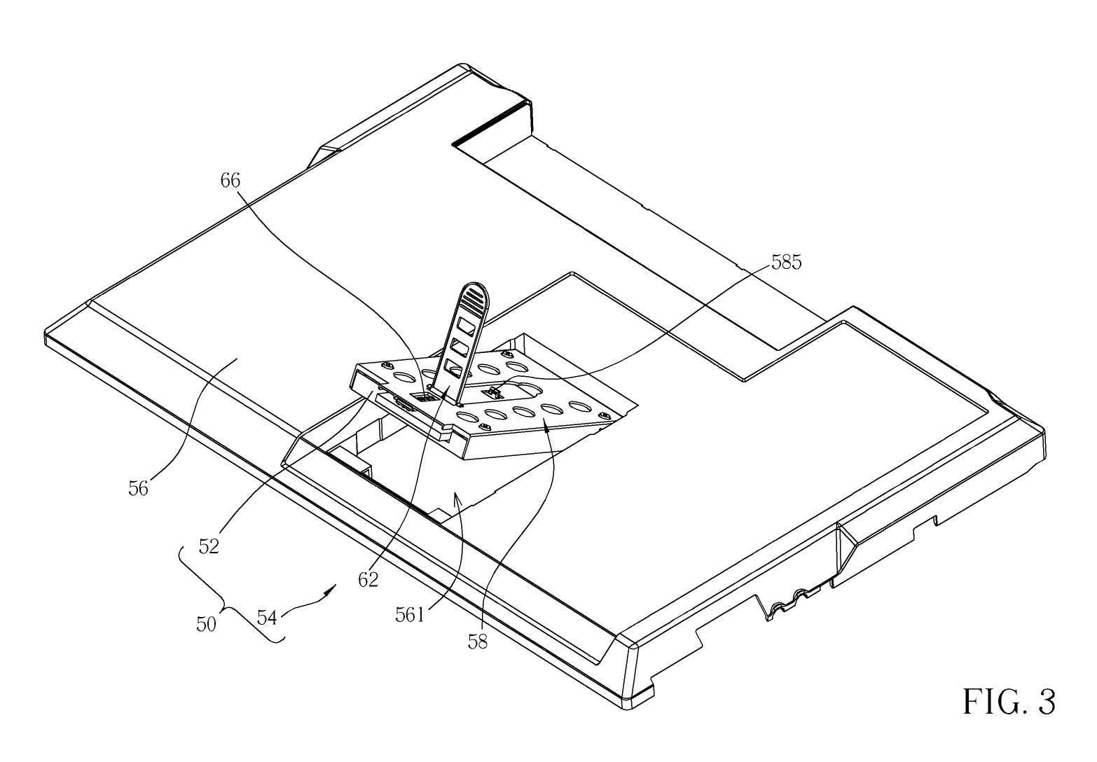

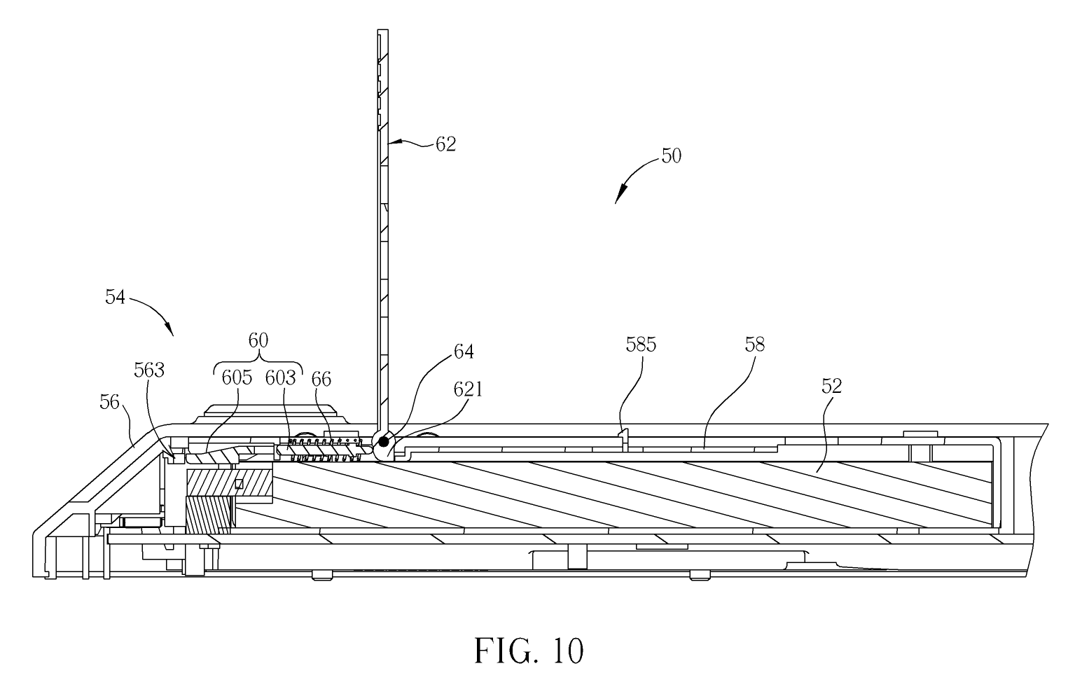

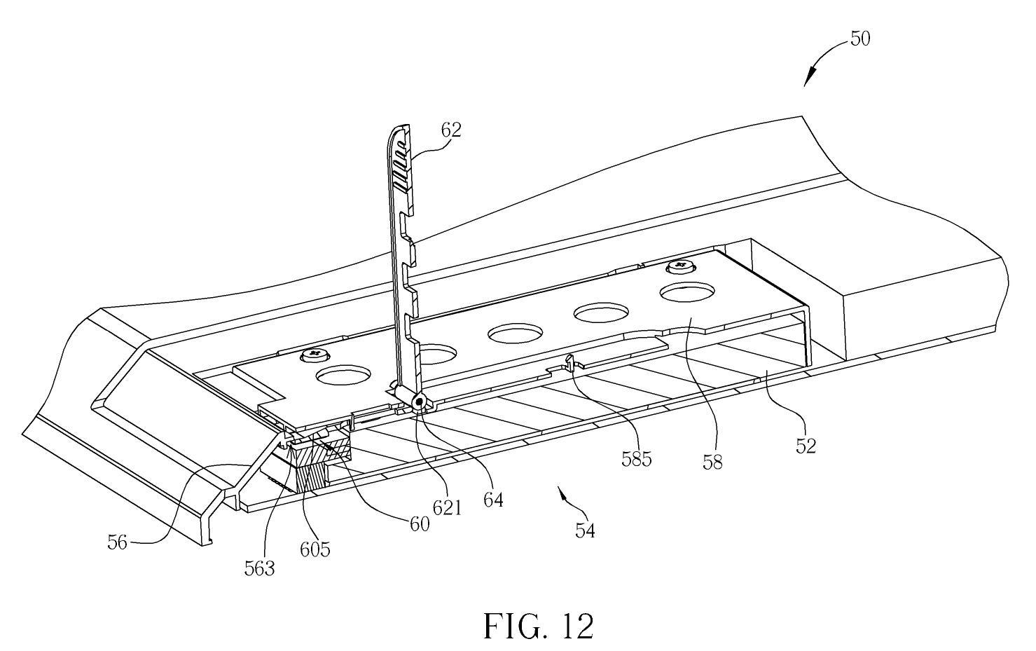

As shown in FIG. 2, FIG. 8, FIG. 10 and FIG. 12, when the removable module 52 is taken out from the accommodating space 561 of the housing 56, first of all, the wedging part 585 is pushed outward so as to release engagement of the wedging part 585 and the handle 62. Then, the handle 62 is rotated to a releasing position, and the protruding part 621 on the end of the handle 62 is rotated to separate from the latch component 60. For example, when the handle 62 rotates to a position substantially perpendicular to the casing 58, the protruding part 621 is substantially perpendicular to the latch component 60 and separates from the latch component 60. At this time, the resilient component 66 can recover from the compressed state to the initial state since the resilient component 66 is no longer compressed by the latch component 60. That is, the resilient component 66 can provide the latch component 60 with an elastic restoring force so as to drive the latch component 60 to separate from the fastening slot 563. When the wedging part 585 is pushed outward, the latch component 60 can slightly push the protruding part 621 since the resilient component 66 drives the latch component 60 to move toward the protruding part 621 of the handle 62. Accordingly, the handle 62 pivoting on the pin 64 moves upwards for users to pull the handle 62. Afterwards, as shown in FIG. 3, the handle 62 is pulled upwards so as to lift the removable module 52 to separate from the accommodating space 561 of the housing 56. Then, the removable module 52 is guided by the track 565 of the housing 56 for being pulled outwards in an inclined direction, so as to complete action of pulling out the removable module 52.

It should be noticed that a connector of the removable module 52 can be still connected to a connector of a circuit board of the electronic device 50 when the latch component 60 separates from the fastening slot 563 and the handle has not been pulled upwards yet. In other words, the removable module 52 is still in an operating state until the handle 62 is pulled upwards. The connector of the removable module 52 can be disconnect from the connector of the circuit board of the electronic device 50 and the removable module 52 is shut down when the handle 62 has been pulled upwards and the removable module 52 has been lifted to separate from the accommodating space 561 of the housing 56. On the other hand, the removable module 52 can be guided by the track 565 of the housing 56 for being disposed in the accommodating space 561 in an inclined direction when the removable module 52 is installed in the accommodating space 561 of the housing 56. Afterwards, the handle 62 rotates to the fixing position so as to make the latch component 60 be locked in the fastening slot 563. Operational principle is the same as mentioned above, and detailed description will be omitted herein for simplicity.

Compared with the prior art, the present invention provides the fixing mechanism for fastening the removable module without using screws and allows the user to disassemble the removable module only by one hand. That is, when the user lifts the removable module by one hand, the fixing mechanism for fastening the removable module is released simultaneously. When the removable module is disposed in the accommodating space and the handle is fixed, the fixing mechanism fastens the removable module simultaneously. Accordingly, the present invention reduces difficulty of assembly, labor hour of assembly and cost of assembly, so as to enhance convenience of assembly.

Those skilled in the art will readily observe that numerous modifications and alterations of the device and method may be made while retaining the teachings of the invention.

What is claimed is:

1. A fixing mechanism for fixing a removable module, comprising:
a housing, an accommodating space and a fastening slot being formed on the housing, and the accommodating space being used for accommodating the removable module;
a casing for covering the removable module;
a latch component installed on the casing in a slidable manner;
a handle connected to the casing in a rotatable manner, an end of the handle pushing the latch component to engage inside the fastening slot for fixing the removable module inside the accommodating space when the handle rotates to a fixing position; and
a resilient component connected to the latch component for driving the latch component to separate from the fastening slot when the handle rotates to a releasing position and the end of the handle separates from the latch component.

2. The fixing mechanism of claim 1, wherein the casing comprises a guiding post, the housing comprises a track and a hole, and the track is used for guiding the guiding post to move in an inclined direction so as to be inserted into the hole.

3. The fixing mechanism of claim 1, wherein the casing comprises a wedging part for engaging the handle when the handle rotates to the fixing position.

4. The fixing mechanism of claim 1, further comprising a pin disposed on the casing, and the end of the handle sheathing the pin so as to be pivotally connected to the casing.

5. The fixing mechanism of claim 1, wherein a protruding part is disposed at the end of the handle for pushing the latch component .

6. The fixing mechanism of claim 1, wherein the latch component comprises a positioning post, the resilient component sheathes the positioning post, and an end of the resilient component abuts against the casing and the other end of the resilient component abuts against the latch component.

7. The fixing mechanism of claim 6, wherein the resilient component is a spring.

8. The fixing mechanism of claim 1, wherein a slot is formed on the latch component, and the casing comprises a hook engaging inside the slot of the latch component in a slidable manner.

9. The fixing mechanism of claim 1, wherein an inclined structure is formed on an end of the latch component, and the inclined structure is used for guiding the end of the latch component to be disposed in the fastening slot.

10. An electronic device comprising:
a removable module; and
a fixing mechanism for fixing the removable module, comprising:
a housing, an accommodating space and a fastening slot being formed on the housing, and the accommodating space being used for accommodating the removable module;
a casing for covering the removable module;
a latch component installed on the casing in a slidable manner;
a handle connected to the casing in a rotatable manner, an end of the handle pushing the latch component to engage inside the fastening slot for fixing the removable module inside the accommodating space when the handle rotates to a fixing position; and
a resilient component connected to the latch component for driving the latch component to separate from the fastening slot when the handle rotates to a releasing position and the end of the handle separates from the latch component.

11. The electronic device of claim 10, wherein the casing comprises a guiding post, the housing comprises a track and a hole, and the track is used for guiding the guiding post to move in an inclined direction so as to be inserted into the hole.

12. The electronic device of claim 10, wherein the casing comprises a wedging part for engaging the handle when the handle rotates to the fixing position.

13. The electronic device of claim 10, further comprising a pin disposed on the casing, and the end of the handle sheathing the pin so as to be pivotally connected to the casing.

14. The electronic device of claim 10, wherein a protruding part is disposed at the end of the handle for pushing the latch component.

15. The electronic device of claim 10, wherein the latch component comprises a positioning post, the resilient component sheathes the positioning post, and an end of the resilient component abuts against the casing and the other end of the resilient component abuts against the latch component.

16. The electronic device of claim 15, wherein the resilient component is a spring.

17. The electronic device of claim 10, wherein a slot is formed on the latch component, and the casing comprises a hook engaging inside the slot of the latch component in a slidable manner.

18. The electronic device of claim 10, wherein an inclined structure is formed on an end of the latch component, and the inclined structure is used for guiding the end of the latch component to be disposed in the fastening slot.
